(19) United States
(12) Patent Application Publication
(10) Pub. No.: US 2026/0177377 A1
(43) Pub. Date: Jun. 25, 2026

(54) INDIRECT REFLECTIVE METROLOGY FOR SURFACE CONDITION MEASUREMENT

(71) Applicant: Applied Materials, Inc., Santa Clara, CA (US)

(72) Inventors: CHENFEI HU, Milpitas, CA (US); MICHAEL CHO, Sunnyvale, CA (US); CHIEN-MIN LIAO, San Jose, CA (US); TOM CHO, Santa Clara, CA (US); HARI PONNEKANTI, Santa Clara, CA (US)

(21) Appl. No.: 18/990,880

(22) Filed: Dec. 20, 2024

(51) Int. Cl. G01B 11/30

(52) U.S. Cl. CPC G01B 11/303

(57) ABSTRACT

Embodiments described herein relate to a method that includes emitting a beam from a laser into a first end of a channel within a workpiece, and detecting an intensity of the beam with a camera at a second end of the channel. In an embodiment, the first end of the channel and the second end of the channel are on the same surface of the workpiece, and the channel is curved. In an embodiment, the method further includes determining if the intensity of the beam is below a predetermined threshold

### BACKGROUND

### 1) Field

Embodiments relate to the field of semiconductor manufacturing and, in particular, indirect reflective metrology for surface condition measurements of internal channels in gas delivery systems.

### 2) Description of Related Art

Gasses are often delivered to semiconductor processing tools for various processing operations. A gas stick is used to control the flow rate and/or other parameters of the gas flow. Traditionally, the gas stick is manufactured with subtractive manufacturing processes. However, such processing is time intensive and relatively expensive. Additionally, curved interior channels within the gas stick are difficult to manufacture, if not impossible. Accordingly, three-dimensional (3D) printing has been proposed as a way to manufacture the gas stick.

While 3D printing processes have improved over time, achieving the desired surface roughness for embedded channels is still challenging. As such, inspection processes may still be necessary in order to confirm that the surfaces of the embedded channels meet the desired specifications. However, existing metrology processes are either destructive (e.g., cross-sectioning and measuring) or expensive. For example, CT or X-ray inspection are expensive and time consuming. Accordingly, there are currently no metrology inspection processes for embedded channels that are compatible with a high volume manufacturing (HVM) environment.

### SUMMARY

Embodiments described herein relate to a method that includes emitting a beam from a laser into a first end of a channel within a workpiece, and detecting an intensity of the beam with a camera at a second end of the channel. In an embodiment, the first end of the channel and the second end of the channel are on the same surface of the workpiece, and the channel is curved. In an embodiment, the method further includes determining if the intensity of the beam is below a predetermined threshold.

Embodiments described herein relate to an apparatus that includes a laser, and a first mount with an optics module, where the optics module is optically coupled to the laser. In an embodiment, the apparatus further includes a second mount for securing a camera, where the camera is configured to measure an intensity of a laser beam from the laser after the laser beam passes through the optics module and passes through a channel of a workpiece.

Embodiments described herein relate to a method that includes measuring a surface roughness of a channel within a workpiece with a laser that is optically coupled to a first end of the channel and a camera that is optically coupled to a second end of the channel with a first measurement setup. In an embodiment, the method further includes measuring the surface roughness of the channel within the workpiece with the laser that is optically coupled to the first end of the channel and the camera that is optically coupled to the second end of the channel with a second measurement setup that is different than the first measurement setup.

### BRIEF DESCRIPTION OF THE DRAWINGS

FIG. 1A is an exploded view perspective illustration of a gas stick and the components coupled to the gas stick, in accordance with an embodiment.

FIG. 1B is a cross-sectional illustration of a gas stick that illustrates the curved channels that are embedded within the gas stick, in accordance with an embodiment.

FIG. 2A is a cross-sectional illustration of a portion of a gas stick that depicts an optical measurement technique to measure a surface roughness of the embedded channel, in accordance with an embodiment.

FIG. 2B is a cross-sectional illustration of a portion of a gas stick that depicts an optical measurement technique with a different entrance angle for a laser beam that passes through the embedded channel, in accordance with an embodiment.

FIG. 2C is a cross-sectional illustration of a portion of a gas stick that depicts an optical measurement technique with the embedded channel partially filled with a fluid, in accordance with an embodiment.

FIG. 3 is a cross-sectional illustration of a portion of a gas stick that depicts a measurement system that can be coupled to a surface of the gas stick to implement an optical measurement technique to determine a surface roughness of a channel embedded in the gas stick, in accordance with an embodiment.

FIG. 4 is a flow diagram depicting a process for determining a surface roughness of an embedded channel with an optical measurement process, in accordance with an embodiment.

FIG. 5 is a flow diagram depicting a process for measuring a surface roughness of an embedded channel with a plurality of optical measurement setups, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include reflective metrology for surface condition measurements of internal channels in gas delivery systems. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, semiconductor processing tools use gas sticks in order to control the flow of processing gasses into the chamber. In order to improve the flow properties of the gas sticks, 3D printing has been used. 3D printing allows for the fabrication of curved channels within the gas stick in a cost effective manner. However, the 3D printing process may result in surfaces of the embedded channels that have surface roughnesses that are higher than desired. High surface roughnesses may result in the generation of micro-turbulence along the gas delivery path, which may negatively impact performance of the semiconductor processing tool.

Accordingly, processes for inspecting the surface roughness of embedded channels are needed in order to determine if a gas stick is suitable for use in a semiconductor processing tool, or if the gas stick needs to be reworked (e.g., the channel needs additional polishing, or the like). Further, the inspection process should be compatible with high volume manufacturing (HVM) environments. For example, destructive testing and/or expensive and time consuming imaging (e.g., CT, X-ray, etc.) are not suitable for such environments. Further, traditional profilometer techniques are not compatible with the curved surfaces of the embedded channels.

As such, embodiments disclosed herein may include an optical measurement technique that passes a laser beam through the embedded channel. The reflections along the surfaces of the embedded channel will reduce the intensity of the laser beam, and the intensity can be measured with a camera at an opposite end of the channel. When the surface roughness is high, the reflections against the surfaces may significantly reduce the intensity of the laser beam. Accordingly, the gas stick may be rejected when the measured intensity is below a predetermined threshold, or the gas stick may need rework (e.g., polishing).

In some embodiments, the optical measurement process may be implemented by an apparatus that is easily coupled to the gas stick. For example, a first mounting brackets that retains an optics module may be coupled by an inlet of the channel, and a second mounting bracket that retains the camera may be mounted at an outlet of the channel. The mounting brackets may be clipped to the gas stick, magnetically attached to the gas stick, bolted to the gas stick, or mechanically coupled with any other suitable non-permanent attachment solution. As such, the mounting brackets can be moved to different channels on the gas stick quickly and/or moved between different gas sticks. This allows for HVM compatibility. Further, the use of such a solution is beneficial since the optical measurement process may be implemented by operators that do not require intensive training, experience, and/or specialized skill sets.

In an embodiment, the optical measurement process may include a single measurement setup. In other embodiments, a plurality of different measurement setups may be used for each channel. For example, multiple setups may include emitting the laser beam into the channel at different angles, and/or the channel may be partially filled with a fluid (e.g., to induce reflection at different points along the channel). Different wavelengths may also be used in different setups in some embodiments.

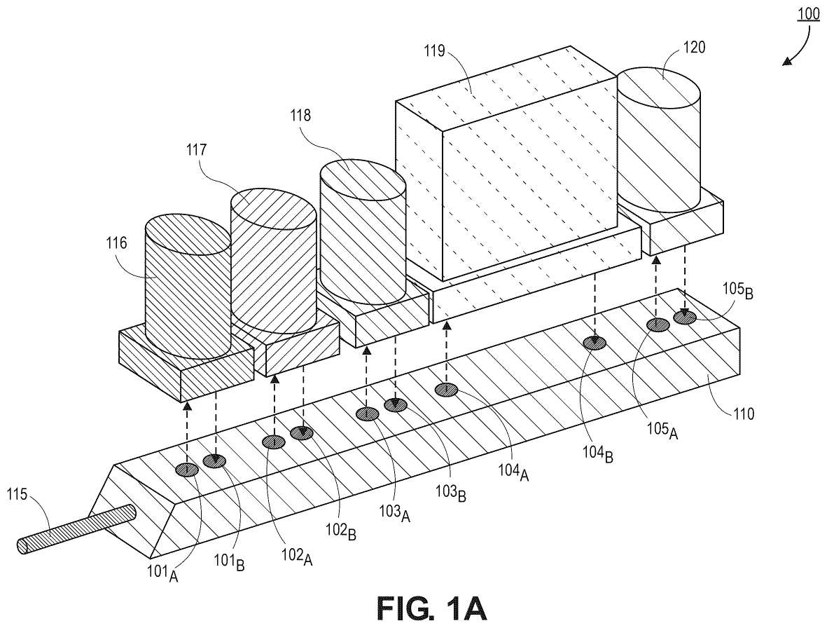

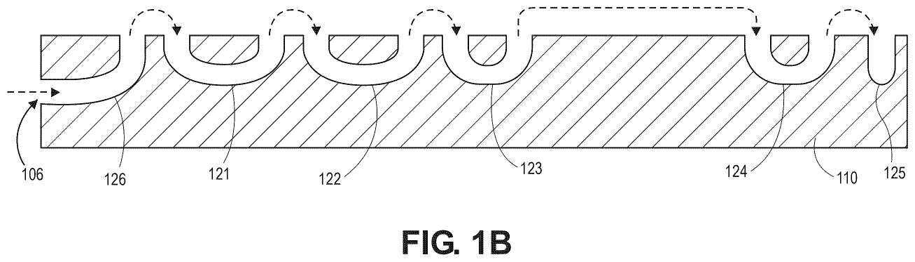

Referring now to FIG. 1A, an exploded perspective view illustration of a gas stick assembly 100 is shown, in accordance with an embodiment. In an embodiment, the gas stick assembly 100 may comprise a gas stick 110 and a plurality of components 116-120 that are coupled to the gas stick 110. In an embodiment, the gas stick 110 may include a plurality of embedded channels (not visible in FIG. 1A). Each of the channels may include an inlet and an outlet. For example, each channel may include an inlet 101_{A} and an outlet 101_{B}. Each of the channels have inlets and outlets labeled with different corresponding numbers (e.g., inlet 102_{A} and outlet 102_{B}, inlet 103_{A} and outlet 103_{B}, inlet 104_{A} and outlet 104_{B}, inlet 105_{A} and outlet 105_{B}).

As indicated by the dashed arrows, each of the inlet and outlet pairs may be fluidically coupled to a different component 116-120. In some embodiments, the components 116-120 may be coupled to the gas stick by fasteners (not shown), such as bolts, screws, or the like. Gaskets, O-rings, and/or other interface materials to provide substantially leak free seals between the gas stick 110 and the components 116-120. In an embodiment, components 116, 117, 118, and 120 may include one or more different types of valves, and the component 119 may be a mass flow controller (MFC). Though, any suitable components may be coupled to the gas stick 110 in other embodiments. In an embodiment, the components 116-120 may be used to control the flow of gas from a gas inlet tube 115 to a chamber (not shown in FIG. 1A). The gas inlet tube 115 may be fluidly coupled to a gas source (not shown), such as an ampoule or the like.

In an embodiment, the gas stick 110 may comprise a metallic material, such as stainless steel, aluminum, and/or the like. The gas stick 110 may be fabricated with any suitable process. However, a particular embodiment may include fabricating the gas stick 110 with a 3D printing process. The use of a 3D printing process may allow for the embedded channels to be formed with curved surfaces. The use of curved surfaces may be beneficial to improve the flow characteristics of gas that passes through the gas stick assembly 100.

Referring now to FIG. 1B, a cross-sectional illustration of the gas stick 110 is shown, in accordance with an embodiment. In an embodiment, the gas stick 110 may include a monolithic metallic body with a plurality of embedded channels. For example, six channels 121-126 are shown in FIG. 1B. In an embodiment, an inlet 106 is provided along a side of the gas stick 110. The inlet may be at a first end of a channel 126 that curves up towards a top surface of the gas stick 110. As shown, additional channels 121-124 include both the input and output along the top surface of the gas stick 110. The dashed arrows indicate the path of the gas as it flows out of the gas stick 110 and into a component, and from the component back into the gas stick 110. Though, the components coupled to the top surface of the gas stick 110 are omitted for simplicity. In an embodiment, the channel 125 may exit the gas stick 110 along a plane out of the view of FIG. 1B.

As shown, the channels 121-126 may each comprise a curved path. The fabrication of curved paths may be enabled through the use 3D printing processes, as described in greater detail herein. However, due to the curved nature of the channels 121-126, inspection of surface roughnesses is difficult. Accordingly, embodiments disclosed herein may include an optical inspection process in order to determine if the channels 121-126 meet a desired surface roughness specification.

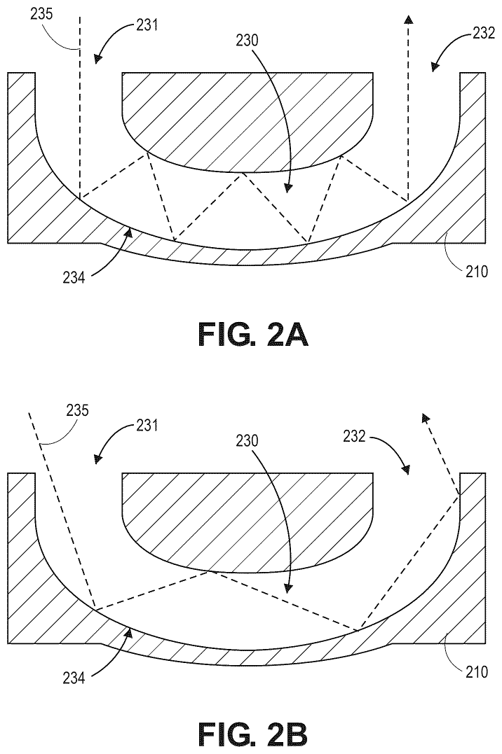

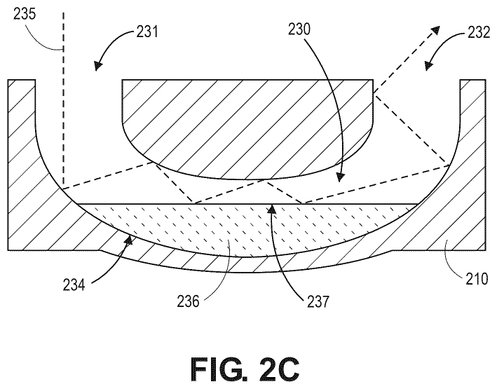

Referring now to FIGS. 2A-2C , a series of cross-sectional illustrations that depict a process for inspecting a surface roughness of a channel 230 that is embedded within a gas stick 210 is shown, in accordance with an embodiment. Generally, the inspection process is an optical process. For example, electromagnetic radiation (e.g., a beam from a laser) is propagated through the embedded channel 230. Due to the curvature of the channel 230, the laser beam reflects off of surfaces 234 of the channel 230 one or more times before exiting the channel 230. Each reflection at a location along the surface 234 may reduce an intensity of the laser beam. A difference between the initial intensity of the laser beam and an intensity of the laser beam after passing through the channel 230 can be determined (e.g., by a camera).

The difference in intensity may be correlated to a surface roughness of the surface 234. For example, a rougher surface may absorb more energy from the laser beam, and the resulting intensity will be lower. The correlation of intensity to surface roughness may provide a binary measurement of the surface roughness (e.g., a pass/fail determination for having a desired surface roughness), or the correlation may provide a specific surface roughness value for the surface 234 of the channel 230.

Referring now to FIG. 2A, a cross-sectional illustration of a portion of a gas stick 210 is shown, in accordance with an embodiment. In an embodiment, the gas stick 210 may comprise an embedded channel 230. The channel 230 may include an inlet 231 at a first end of the channel 230 and an outlet 232 at a second end of the channel 230. As shown, the inlet 231 and the outlet 232 are provided along the same surface of the gas stick 210. For example, the inlet 231 and the outlet 232 are provided along the top surface of the gas stick 210. Since the inlet 231 and the outlet 232 are provided on the same surface of the gas stick 210, the channel 230 includes at least a two dimensional path through the body of the gas stick 210.

That is, the channel 230 may have a Z-component (to bring the channel 230 to a depth within the gas stick 210), and an X-component (to extend the channel 230 laterally across the gas stick 210). While shown as having an X-component and a Z-component, the channel 230 may also include a Y-component (i.e., into and out of the plane of FIG. 2A) in some embodiments.

In an embodiment, the channel 230 is curved. That is, the surface 234 of the channel may not include any corners (e.g., where a substantially linear first surface meets a substantially linear second surface at an angle). The presence of a curved surface 234 enables optical inspection due to the propagation of a laser beam 235 through the channel 230 by reflecting off of the surface 234 at various locations. For example, a laser beam 235 (from a laser source (not shown)) is propagated into the channel 230 through the inlet 231. The laser beam 235 reflects off of the surface 234 a plurality of times before the laser beam 235 exits the outlet 232 of the channel 230. The laser beam 235 can then be measured by a camera (not shown) to determine how much the intensity of the laser beam 235 decreases relative to the intensity at the inlet 231 of the channel 230.

It is to be appreciated that the surface roughness that is measured by the optical inspection technique will correspond to the surface roughness of the locations of the surface 234 where reflections occur. Further, an average value of the surface roughness may be determined, since the total decrease in intensity is measured instead of isolating a measurement at each of the reflection locations. In some instances, such an average measurement is sufficient. However, other embodiments may require a more holistic analysis of the surface roughness of the surface 234 of the channel 230.

Referring now to FIG. 2B, a cross-sectional illustration of a portion of a gas stick 210 is shown, in accordance with an additional embodiment. As shown, the gas stick 210 in FIG. 2B is substantially similar to the gas stick 210 in FIG. 2A. However, the entrance angle of the laser beam 235 is different. As shown, the alternate entrance angle of the laser beam 235 allows for different locations along the surface 234 of the channel 230 to be measured with the optical inspection technique. In some embodiments, the optical inspection technique may include a plurality of different measurement setups with each of the setups including a different entrance angle for the laser beam 235. In yet another embodiment, the laser beam 235 may be scanned across a plurality of angles in order to provide an average surface roughness that accounts for a larger percentage of the overall surface 234 of the channel 230.

In some embodiments, a region of the channel 230 may be known to be problematic with respect to surface roughness. In such an instance, the entrance angle of the laser beam 235 may be set to specifically target the region that is known to have problematic surface roughness issues. While entrance angle of the laser beam 235 is one example of a parameter that can be controlled in the measurement setup, other parameters may also be changed and/or controlled.

Referring now to FIG. 2C, a cross-sectional illustration of a portion of a gas stick 210 is shown, in accordance with yet another embodiment. The gas stick 210 in FIG. 2C may be substantially similar to the gas stick 210 in FIG. 2A, with the exception of the addition of a fluid 236 that is added into the channel 230. In an embodiment, the fluid 236 may at least partially fill the channel 230. In an embodiment, the fluid 236 may be used to provide a different reflective surface within the channel 230 and/or to change the angle of reflections due to different indices of refraction provided by the fluid 236. The fluid 236 may comprise any suitable fluid, such as water, oil, or the like.

As shown in FIG. 2C, the fluid 236 may have a top surface 237 that is provided below an upper portion of the surface 234. This allows for a continuous open path from the inlet 231 to the outlet 232 to remain. As shown by the path of the laser beam 235, the reflections may occur along the top surface 237 of the fluid 236 and reflect back off an upper portion of the surface 234 before exiting the outlet 232. Accordingly, the use of a fluid 236 may be used to preferentially measure the surface roughness of the upper portion of the surface 234 of the channel 230 in some embodiments.

It is to be appreciated that different measurement setups may be used in combination with each other. For example, filling at least a portion of the channel 230 with a fluid 236 and altering an angle of the laser beam 235 may both be used as options to selectively measure surface roughnesses of different portions of the surface 234 of the channel 230.

In the embodiments described with respect to FIGS. 2A-2C , the measurement components are omitted for simplicity. However, it is to be appreciated that a measurement system with several components may be mounted to the gas stick easily in order to rapidly perform surface roughness measurements of multiple channels within a single gas stick, and/or to provide measurements of many different gas sticks over a relatively short period of time. In some embodiments, the measurement system may be relatively stationary, and the gas sticks are coupled to the stationary measurement system. In other embodiments, the measurement system may be coupled to and subsequently removed from the gas stick.

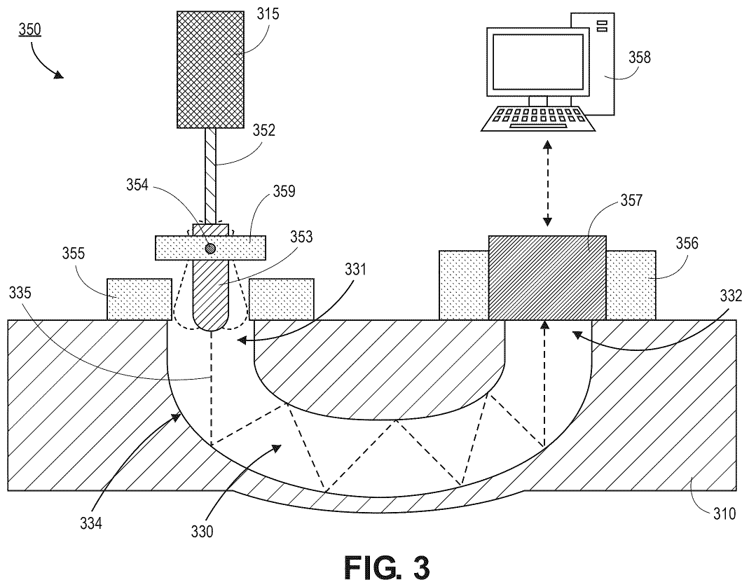

Referring now to FIG. 3, a cross-sectional illustration of an optical measurement system 350 is shown, in accordance with an embodiment. As shown, the optical measurement system 350 may be coupled to a gas stick 310. The gas stick 310 may be similar to any of the gas sticks described in greater detail herein. For example, the gas stick 310 may comprise a channel 330 with an inlet 331 at a first end and an outlet 332 at a second end. The channel 330 may have a curved surface 334.

As shown, the measurement system 350 may comprise a first mount 355 that is coupled to the gas stick 310 proximate to the inlet 331 at a first end of the channel 330. The first mount 355 may be temporarily coupled to the gas stick 310 with any suitable fastening structure (e.g., clips, magnets, pins, bolts, screws, adhesive, and/or the like). The first mount 355 may include a positioning member 359 that is configured to secure an optics module 353. The optics module 353 may include one or more lenses, mirrors, filters, and/or the like. The optics module 353 may be used to focus and/or orient the laser beam 335 that is delivered to the optics module 353 from a laser 315. The optics module 353 may be optically coupled to the laser 315 by an optical fiber 352, or any other suitable optical path. In an embodiment, the laser 315 may be configured to emit a laser beam 335 with a single frequency (or narrow band of frequencies), or the laser 315 may be configured to emit laser beams 335 with a plurality of different frequencies (or a plurality of different narrow bands of frequencies).

In an embodiment, the positioning member 359 may be adjustable to change a position and/or orientation of the optics module 353 so that the laser beam 335 can be propagated into the channel 330 at a plurality of different entry angles and/or from different distances from the gas stick 310. For example, a pivot point 354 may be used to alter an angle of the optics module 353 (as indicated by the dashed outlines of the optics module 353). The ability to change the position and/or angle of the optics module 353 allows for the use of different measurement setups, which can be used to measure the surface roughness of different portions of the surface 334 of the channel 330.

As shown, the laser beam 335 is emitted into the channel 330 and reflects off of the surface 334 at different locations as the laser beam 335 propagates through the channel 330. Ultimately, the laser beam 335 may exit the channel 330 at the outlet 332 at the second end of the channel 330. In an embodiment, a second mount 356 is coupled to the gas stick 310 at the second end of the channel 330. In an embodiment, the second mount 356 may be temporarily coupled to the gas stick 310 with any suitable fastening structure (e.g., clips, magnets, pins, bolts, screws, adhesive, and/or the like). The second mount 356 may be configured to secure a camera 357.

In an embodiment, the camera 357 may be suitable for measuring an intensity of the laser beam 335 after the laser beam 335 has exited the channel 330. The camera 357 may include any type of digital image sensor, such as a charge-coupled device (CCD) image sensor or a CMOS image sensor. In an embodiment, the camera 357 may be communicatively coupled (e.g., by wireless communication, a data cable, or the like) to a processor 358 (e.g., a computer, a tablet, a server, or the like). The intensity data from the camera 357 may be sent to the processor 358, and the processor 358 may calculate a surface roughness from the intensity data.

In an embodiment, the surface roughness may be determined by detecting a difference between an intensity of the laser beam 335 before the laser beam 335 enters the channel 330 and an intensity of the laser beam 335 as measured by the camera 357 after the laser beam 335 passes through the channel 330. The change in intensity may be used to determine a binary pass/fail condition for the surface 334 of the channel 330, or the change in intensity may be used to give a quantitative measure of the surface roughness of the surface 334 of the channel 330.

As noted above, the optical measurement system 350 may be used to measure the surface roughness of the surface 334 of the channel 330 using a single measurement setup, or the optical measurement system 350 may be used to measure the surface roughness of the surface 334 of the channel 330 using a plurality of different measurement setups. In an embodiment, if the gas stick 310 is found to have a channel 330 with a surface roughness that does not meet a predetermined specification, the channel 330 of the gas stick 310 may be reworked (e.g., polished or the like), or the gas stick 310 may be scrapped.

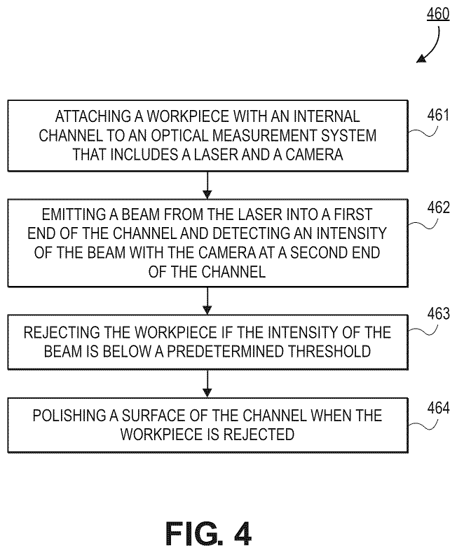

Referring now to FIG. 4, a flow diagram depicting a process 460 for measuring a surface roughness of an embedded channel in a workpiece is shown, in accordance with an embodiment. In an embodiment, the workpiece may be a gas stick similar to any of the gas sticks described in greater detail herein. Though, embodiments disclosed herein may include using the process 460 to measure surface roughnesses of embedded channels for any type of device or component.

In an embodiment, the process 460 may begin with operation 461, which comprises attaching a workpiece with an internal channel to an optical measurement system that includes a laser and a camera. In an embodiment, the optical measurement system may be similar to the optical measurement system 350 described in greater detail herein. For example, the optical measurement system may comprise a laser, a first mount for securing an optics module, a second mount for securing a camera, and a processor that is communicatively coupled to the camera.

In an embodiment, the process 460 may continue with operation 462, which comprises emitting a beam from the laser into a first end of the channel and detecting an intensity of the beam with the camera at a second end of the channel. For example, the first mount may be provided proximate to the first end of the channel. The beam from the laser may be optically coupled to an optics module secured by the first mount. In an embodiment, the first mount may be configured to orient the optics module so that the beam enters the first end of the channel at a desired angle. In an embodiment, the beam may reflect off the surface of the channel one or more times before being detected by the camera at the second end of the channel. In an embodiment, the first mount and the second mount may be coupled to the same surface of the workpiece similar to other embodiments described herein. That is, the channel may be a curved channel that enters and exits the same surface of the workpiece.

In an embodiment, the process 460 may continue with operation 463, which comprises rejecting the workpiece if the intensity of the beam is below a predetermined threshold. In an embodiment, the predetermined intensity threshold may correspond to a maximum allowable surface roughness. If the intensity is below the threshold, then the surface of the channel is too rough and does not meet the desired specification.

In an embodiment, the process 460 may continue with operation 464, which comprises polishing a surface of the channel when the workpiece is rejected. In an embodiment, the polishing process may be used to reduce the surface roughness of the surface of the channel. After the polishing, the process 460 may be repeated in order to determine if the reworked workpiece meets the desired surface roughness specification.

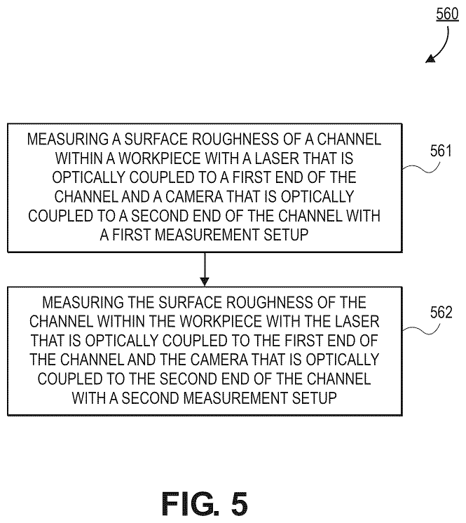

Referring now to FIG. 5, a flow diagram depicting a process 560 for measuring a surface roughness of a channel of a workpiece is shown, in accordance with an embodiment. In an embodiment, the workpiece may be a gas stick similar to any of the gas sticks described in greater detail herein. Though, embodiments disclosed herein may include using the process 560 to measure surface roughnesses of embedded channels for any type of device or component.

In an embodiment, the process 560 may begin with operation 561, which comprises measuring a surface roughness of a channel within the workpiece with a laser that is optically coupled to a first end of the channel and a camera that is optically coupled to a second end of the channel with a first measurement setup. In an embodiment, the laser and the camera may be part of an optical measurement system similar to the optical measurement system 350 described in greater detail herein.

In an embodiment, the first measurement setup may include setting a desired angle of the beam of the laser as the beam enters the channel, a frequency of the beam of the laser, the presence or absence of a fluid in the channel, and/or any of the other parameters described in greater detail herein. The first measurement setup may be used to find a surface roughness of a first portion of the surface of the channel.

In an embodiment, the process 560 may continue with operation 562, which comprises measuring the surface roughness of the channel within the workpiece with the laser that is optically coupled to the first end of the channel and the camera that is optically coupled to the second end of the channel with a second measurement setup. The second measurement setup may be different than the first measurement setup. For example, one or more parameters, such as the angle of the beam of the laser as the beam enters the channel, a frequency of the beam of the laser, the presence or absence of a fluid in the channel, and/or any of the other parameters described in greater detail herein may be changed relative to the first measurement setup.

The second measurement setup may be used to determine a surface roughness of a second portion of the surface of the channel within the workpiece. As such a more comprehensive analysis of a surface of the channel may be determined in order to decide if the channel meets desired specifications. While two different measurement setups are described in process 560, it is to be appreciated that any number of different measurement setups may be used in accordance with various embodiments.

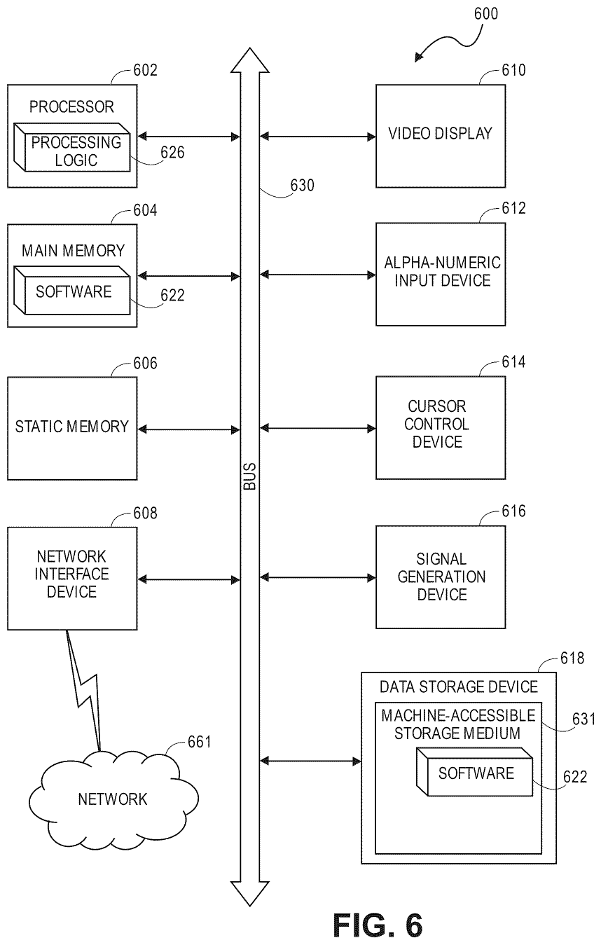

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method comprising:
emitting a beam from a laser into a first end of a channel within a workpiece;
detecting an intensity of the beam with a camera at a second end of the channel, wherein the first end of the channel and the second end of the channel are on the same surface of the workpiece, and wherein the channel is curved; and
determining if the intensity of the beam is below a predetermined threshold.

2. The method of claim 1, further comprising:
polishing a surface of the channel when the intensity of the beam is below the predetermined threshold.

3. The method of claim 1, further comprising:
at least partially filling the channel with a fluid before emitting the beam from the laser into the first end of the channel.

4. The method of claim 1, wherein the first end of the channel and the second end of the channel are on a same surface of the workpiece.

5. The method of claim 1, further comprising:
emitting a second beam from the laser into the first end of the channel, wherein the second beam is emitted into the first end of the channel at an angle that is different than a first angle at which the beam enters the first end of the channel.

6. The method of claim 1, further comprising:
scanning the beam through different entry angles into the first end of the channel.

7. The method of claim 1, wherein the workpiece is a gas stick.

8. An apparatus, comprising:
a laser;
a first mount with an optics module, wherein the optics module is optically coupled to the laser; and
a second mount for securing a camera, wherein the camera is configured to measure an intensity of a laser beam from the laser after the laser beam passes through the optics module and passes through a channel of a workpiece.

9. The apparatus of claim 8, further comprising:
a processor communicatively coupled to the camera.

10. The apparatus of claim 8, wherein the first mount is adjustable to change an angle of the optics module relative to the workpiece.

11. The apparatus of claim 8, wherein the first mount is adjustable to change a distance of the optics module from the workpiece.

12. The apparatus of claim 8, wherein the first mount is coupled to the workpiece with a magnet, a clip, a screw, a bolt, or an adhesive.

13. The apparatus of claim 8, wherein the first mount is configured to be coupled to the workpiece over a first end of the channel and the second mount is configured to be coupled to the workpiece over a second end of the channel.

14. The apparatus of claim 13, wherein the first end of the channel and the second end of the channel are at a same surface of the workpiece.

15. The apparatus of claim 14, wherein the channel has a curved path.

16. The apparatus of claim 8, wherein the workpiece is a gas stick.

17. The apparatus of claim 8, wherein the laser is optically coupled to the optics module by an optical fiber.

18. A method, comprising:
measuring a surface roughness of a channel within a workpiece with a laser that is optically coupled to a first end of the channel and a camera that is optically coupled to a second end of the channel with a first measurement setup; and
measuring the surface roughness of the channel within the workpiece with the laser that is optically coupled to the first end of the channel and the camera that is optically coupled to the second end of the channel with a second measurement setup that is different than the first measurement setup.

19. The method of claim 18, wherein the first measurement setup and the second measurement setup comprise emitting a laser beam from the laser into the channel at different angles.

20. The method of claim 18, wherein the second measurement setup comprises at least partially filling the channel with a fluid.
